(19) United States
(12) Patent Application Publication
(10) Pub. No.: US 2015/0013217 A1
(43) Pub. Date: Jan. 15, 2015

(54) CROSS-FUNCTIONAL ARCHITECTURAL GREENHOUSE GLASS, GREENHOUSES INCLUDING SAME, AND/OR ASSOCIATED METHODS

(71) Applicant: Guardian Industries Corp., Auburn Hills, MI (US)

(72) Inventors: C. Brett JOHNSON, Brighton, MI (US); Lance BONIN, Temperance, MI (US); Bryon ADAMCZYK, Northville, MI (US)

(21) Appl. No.: 13/940,595

(22) Filed: Jul. 12, 2013

(51) Int. Cl. A01G 9/14; H05K 13/00

(52) U.S. Cl. CPC A01G 9/14; H05K 13/00
USPC 47/17; 52/745.19; 29/829

(57) ABSTRACT

Certain example embodiments of this invention relate to cross-functional architectural greenhouse glass, greenhouses including cross-functional architectural greenhouse glass, and/or associated methods. Certain example embodiments involve combining sensor, functional coating, glass patterning, and/or glass composition selection technologies to produce flat or bent substrates suitable for use in such example applications. It advantageously becomes possible in certain example instances to give growers more control over their individual greenhouses (including portions thereof), while also switching from a more qualitative, to a more quantitative, growing operational approach. The customization afforded by certain example embodiments also advantageously enables new efficiencies to be reached, promotes better crop yields, increases profitability for the grower, and/or reduces crop yield cycle time, potentially in ways that are inconsistent with mainstream growing patterns and/or hobbyist or other preconceptions about the standard way(s) in which plants should be grown.

### FIELD OF THE INVENTION

Certain example embodiments of this invention relate to glass suitable for use in greenhouse applications and/or associated techniques. More particularly, certain example embodiments relate to cross-functional architectural greenhouse glass, greenhouses including cross-functional architectural greenhouse glass, and/or associated methods.

### BACKGROUND AND SUMMARY OF EXAMPLE EMBODIMENTS OF THE INVENTION

It is known to use greenhouses and the like to provide environmental protection to crops being grown. Commercial greenhouses oftentimes include walls and/or windows made of laminated plastic sheets (e.g., first and second plastic substrates laminated together with a laminating material or the like). Such plastic articles generally are advantageous because they are lightweight and can relatively easily be bent or otherwise formed into desired shapes and/or sizes appropriate for desired greenhouse designs. They also are generally advantageous in that they provide some a high degree of transparency appropriate for light transmission from the outside environment into the growing environment.

The inventors have realized that glass might have certain advantages over the plastic materials used in conventional greenhouse designs. For instance, glass can provide a higher degree of transparency and oftentimes can be coated quite easily (e.g., with sputter-deposited thin film coatings, coatings that are wet applied from a sol or the like, etc.) because of its comparatively higher softening and/or melting temperature. Glass also can be etched (e.g., using acid-based etchants such as HF-inclusive acid-based etchants and/or mechanical means such as sand blasting) to provide a textured morphology suitable for the scattering of unwanted infrared (IR) wavelengths to shallow angles for their dissipation, and/or the scattering of the visible light components to steeper angles to provide their effective absorption by the plants.

Despite these and other advantages that glass offers, it unfortunately has not been widely adopted by the industry. It is believed that one reason for this lies in the fact that glass is oftentimes seen as being difficult to size, shape, and/or bend. Given the different geometries of windows oftentimes found in greenhouse applications, this difficulty can be seen as a major impediment, leading to the conventional wisdom that it is safer and easier to simply use conventional laminated plastic assemblies.

The inventors have, however, realized that the example advantages described above can be used in different combinations and/or sub-combinations to make glass a more attractive option for greenhouse-type applications. The inventors also have realized that the hot-bending techniques used for automotive applications and some solar applications can be used to form windows for greenhouse-type applications. The ability to use already-existing equipment previously designated for automotive use can be highly advantageous in terms of putting otherwise unused or under-used resources to work for new product entries into new markets. Thus, it will be appreciated that, because of the inventor's recognitions, there is a new possibility to introduce glass into large-scale, potentially high-production greenhouse applications.

One aspect of certain example embodiments relates to providing sensor technology for a greenhouse, e.g., to sense light, temperature, humidity, infrared radiation, weather conditions, etc.

Another aspect of certain example embodiments relates to providing one or more function coatings (e.g., single or double sided antireflection, hydrophilic and/or photocatalytic, UV and/or IR blocking, and/or other coatings) for a greenhouse.

Another aspect of certain example embodiments relates to providing a desired pattern on a glass substrate for a greenhouse to provide desirable haze, diffusion, and/or light scattering for the greenhouse, e.g., by patterning, acid etching, or providing a suitably textured layer.

Another aspect of certain example embodiments relates to providing glass for a greenhouse application that has a glass composition with a desired visible transmission (e.g., of at least 89%, 90%, 91%, etc.).

Another aspect of certain example embodiments relates to providing either flat or bent, heat treated (e.g., thermally tempered and/or heat strengthened) glass for greenhouse applications, e.g., where the glass is coated before or after bending and/or heat treatment.

Yet another aspect of certain example embodiments relates to combining these and/or other aspects, or portions thereof, for use in a novel “smart” greenhouse setting.

In certain example embodiments, a greenhouse is provided. A plurality of glass windows at least partially defines a roof and a sidewall of the greenhouse. At least some of the glass windows comprise a substantially planar glass substrate that supports an antireflective coating on at least one major surface thereof and also has features formed thereon, with the features being sized, shaped, and arranged to scatter light in a first wavelength range in a first direction and to scatter light in a second wavelength range in a second direction. The first and second wavelength ranges and the first and second directions respectively are different from one another. At least one sensor is mounted to at least one of the glass windows. At least one automated subsystem is provided for the greenhouse. A controller, including at least one processor and a memory, is configured to send control signals to the at least one automated subsystem based on data received from the at least one sensor (e.g., to open/close/vent/reposition panels and/or shade baffles, start/stop irrigation, adjust heating/cooling, humidify/dehumidify the chamber, turn on/off lighting, actuate/deactivate a defroster, etc.).

In certain example embodiments, a method of making a window for a greenhouse comprises: providing a substantially planar glass substrate; disposing an antireflective coating on one or both major surfaces of the substrate; forming light scattering features on one of the major surfaces of the substrate, with the features being sized, shaped, and arranged to scatter light in a first wavelength range in a first direction and to scatter light in a second wavelength range in a second direction, and with the first and second wavelength ranges and the first and second directions respectively being different from one another; and mounting at least one sensor to the substrate, with the at least one sensor being configured to gather information relevant to operation of a greenhouse in which the window is installed and having a data output lead connectable to a controller.

In certain example embodiments, a method of assembling a greenhouse is provided. A greenhouse window or the like made according to the example techniques is provided. A plurality of substrates also is provided. The window and the substrates are built into the greenhouse as parts of the roof and/or sidewall(s), with the at least one sensor being on the greenhouse's interior. The data output lead from the at least one sensor of the window is connected to a programmable controller. Automated subsystems of the greenhouse are connected to the programmable controller. The automated subsystems comprise one or more of openable/closable windows and/or shade baffles, irrigation, a heating and/or cooling unit, and/or lighting.

In certain example embodiments, methods of providing insulated glass (IG) units, laminated articles, sized substrates, etc., may be made using these and/or other techniques. Corresponding and/or other products also are envisioned herein.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIGS. 1a-1g are partial perspective schematic views of different greenhouse configurations that may be used in connection with different embodiments;

FIG. 2 is a block diagram showing, schematically, how sensors may be embedded in a greenhouse in accordance with certain example embodiments;

FIG. 3 is a diagram showing how output from the sensor arrays can be used to trigger different automated subsystems in accordance with certain example embodiments;

FIG. 4 is a cross-sectional view of a substrate supporting an optional sputter deposited heat treatable AR coating that may be used in connection with certain example embodiments;

FIG. 5 is an example Ag-based low-E coating that may be used in connection with certain example embodiments;

FIG. 6 is an example ITO-based low-E coating that may be used in connection with certain example embodiments; and

FIG. 7 is a schematic view illustrating operational principles of a light scattering coating that may be used in connection with certain example embodiments.

### DETAILED DESCRIPTION OF EXAMPLE EMBODIMENTS OF THE INVENTION

Certain example embodiments of this invention relate to cross-functional architectural greenhouse glass, greenhouses including cross-functional architectural greenhouse glass, and/or associated methods. Certain example embodiments involve combining sensor, functional coating, glass patterning, and/or glass composition selection technologies to produce flat or bent substrates suitable for use in such example applications.

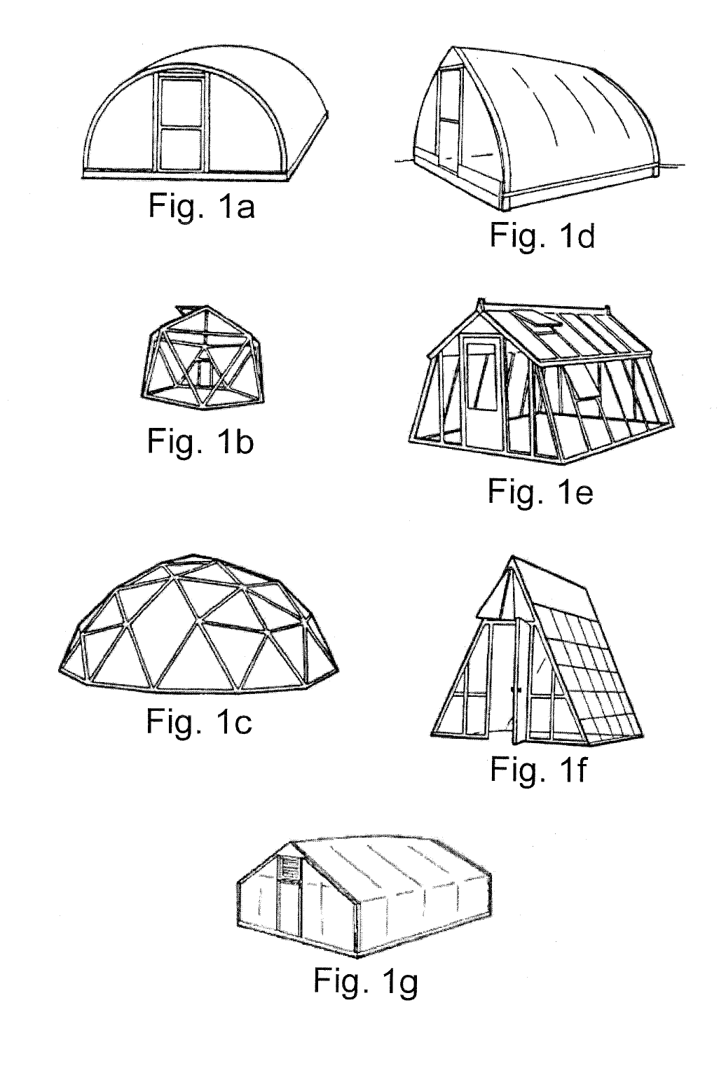

Referring now more particularly to the drawings in which like reference numerals indicate like parts throughout the several views, FIGS. 1a-1g are partial perspective schematic views of different greenhouse configurations that may be used in connection with different embodiments. More particularly, FIG. 1a shows an example Quonset-type greenhouse, FIG. 1b shows an example tri-penta type greenhouse, FIG. 1c shows an example dome-type greenhouse, FIG. 1d shows an example gothic arch type greenhouse, FIG. 1e shows an example slant side type greenhouse, FIG. 1f shows an example A-frame type greenhouse, and FIG. 1g shows an example gable roof type greenhouse.

Many common greenhouse designs are derived from one or both of the Quonset-type greenhouse shown in FIG. 1a and the A-frame type greenhouse shown in FIG. 1f. The Quonset is based upon an arched roof, which allows stresses on the structure to be efficiently transferred down to the ground. Quonset greenhouses may have their arches extend all the way to the ground with no side walls, or the arch may in essence form a roof and gable portion, with side walls extending to the ground. A-frame greenhouses oftentimes include plural supporting trusses that form the roof and gables, and the trusses set on vertical side walls can provide structural stability for the greenhouse. A-frame greenhouses may be even-span A-frame greenhouses (where both roof sections are of equal length), or uneven-span A-frame greenhouses (where roof sections are of an uneven length, or even missing).

Greenhouse frames and/or other supporting structures may be constructed of wood, steel, aluminum, concrete, and/or the like. Concrete, cement, gravel, fabric-covered clay, and/or the like oftentimes are used for flooring materials.

These and/or other greenhouse types (e.g., sawtooth, lean-to, etc.) may be freestanding and may be used for “hobby” or commercial purposes in different example instances. Although one structure is shown in each of FIGS. 1a-1g, multiple of the same or different structures may be connected to form ridge-and-furrow and/or gutter-connected designs, and dividing drop walls, curtains, and the like may be placed between different sections may or may not be present in different instances.

### Example Sensor Related Techniques

Certain example embodiments make use of sensor technology to help drive automation within the greenhouse, potentially enabling growers to move from a qualitative to a more quantitative approach to growing. In certain example embodiments, the sensors may sense or otherwise receive information that provides meaningful data to a grower and/or pertains to operation of the greenhouse. As will be disclosed in detail below, for example, greenhouse roofs may be made to open early in the day, close if rain comes, open to vent out humidity and/or assist in the “rolling away” of built up condensation, close in cases where there are sudden drops in barometric pressure potentially indicative of an approaching storm, etc.

As will be appreciated from the below, the way that the data may be used might seem somewhat counterintuitive. For example, it is generally believed that rain and sunlight generally is good for most plant growth. It is noted, however, that water from rainclouds might actually be disadvantageous in some circumstances, e.g., where growers want to more precisely control the amount of water that the plants receive, in situations where it is desirable to filter impurities and/or add nutrients to water, etc. Similarly, some plants are known to be “shade-loving” and/or thrive in dark environments. The sensor technology described herein advantageously gives the grower precise, quantitative control over these and/or other factors and enables the grower to set up operational aspects in manners that might seem counterintuitive to many hobby growers and/or for many typical growing scenarios but nonetheless are desirable for a particular crop. The ability to customize greenhouse parameters may advantageously enable new efficiencies to be reached, promoting better crop yields, increasing profitability for the grower, and/or reducing crop yield cycle time.

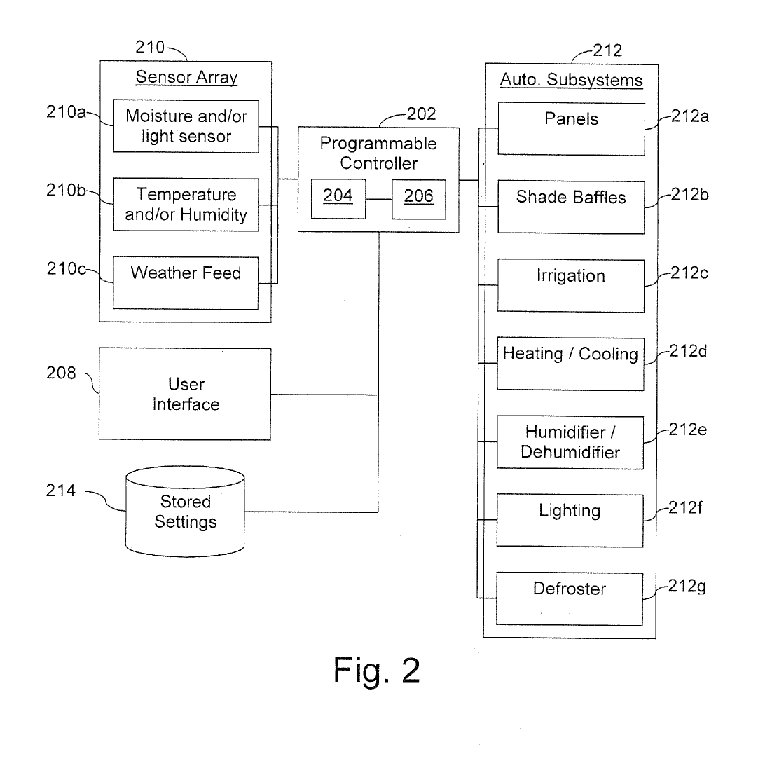

FIG. 2 is a block diagram showing, schematically, how sensors may be embedded in a greenhouse in accordance with certain example embodiments. Such sensors may be used to drive automation and help produce a more efficient, and thus more profitable, greenhouse operation. A programmable controller 202 of the FIG. 2 example system includes processing resources such as, for example, at least one processor 204 and a memory 206 that are operatively coupled together. A user may use a user interface 208 that interfaces with the programmable controller to define how information gathered from the sensor array 210 controls the automated subsystem(s) 212. The user interface 208 may include a display a data entry means (e.g., a keyboard, mouse, touch screen, etc.), and it may be located in or remote from the greenhouse itself. In the latter case, certain example embodiments may include a network or other connection between the user interface and the controller 202 in the greenhouse. Settings may be stored to a storage location (e.g., a non-transitory computer readable storage medium) 214 and, in certain example embodiments, such multiple settings may be stored for different seasons, areas of a greenhouse, etc. The settings may be pre-set, based on preconfigured settings, and/or otherwise user defined in whole or in part. Multiple versions of the settings may be stored and persisted over time in certain example embodiments.

The sensor array 210 may include, for example, a moisture and/or light sensor 210a, a temperature and/or humidity gauge 210b), a link to a Weather feed, etc. The moisture and/or light sensor 210a may be mounted on an interior surface of glass at or near the roof of the greenhouse, e.g., in a location such that it is configured to “see through” the glass roof and detect the presence of rain, ice, fog, and/or other condensation. It additionally or alternatively may be configured to output data concerning the presence of light and, in the presence of light, what spectrum(s) the light occupies. It is noted that at least some of the sensors may be hard-anchored to the roof, e.g., with such sensors and/or leads therefor being embedded in or attached to the glass during and/or after annealing; before, during, and/or after optional heat treatment and/or bending phases; etc.

Various sensors that may be used in the sensor array 210 are shown in the FIG. 2 example embodiments. It will be appreciated, however, that different sensors may be used in place of and/or in addition to those shown in FIG. 2. In any event, returning to the example sensor array 210, a moisture and/or light sensor 210a is shown. The moisture and/or light sensor 210a may incorporate features disclosed in U.S. Publication No. 2013/0024169, the entire contents of which are hereby incorporated herein by reference.

With respect to the moisture-sensing capabilities of certain example embodiments, as is taught by the '169 publication, for example, a plurality of sensing capacitors in a capacitive array or the like is supported by a window of the greenhouse, e.g., on an interior surface thereof, with each capacitor having a different field. A sensing circuit outputs an analog signal that is based on and/or related to the capacitances of the sensing capacitors. A switching circuit is provided in order to selectively switch between different sensing capacitors or different combinations thereof (or even possibly antennas and/or bands), in order to change the sensing field being analyzed and/or change the feature being searched for. For example, the switching circuit may selectively switch between: (a) capacitor(s) for detecting rain on an exterior surface of the window, and (b) capacitor(s) for detecting one or more of ice on an exterior surface of the window, mist on an exterior surface of the window, and/or moisture on an interior surface of the window, etc. The first and second spaced apart capacitor electrodes may be substantially coplanar. The capacitive sensors may have the same or different fractal patterns. A determination as to whether moisture is present on an exterior surface of the greenhouse window may be made by, for example, receiving a signal relating to at least one sensing capacitor, and processing the signal to obtain a signal footprint; and comparing the signal footprint with one or more predetermined signal footprints stored in memory to determine whether a detected material on the external surface of the vehicle is moisture (and the type of moisture) or some other material (e.g., EMI, a human hand, a bird, etc.). In some cases, the determination may involve, for example, receiving data relating to at least two capacitors supported by the greenhouse window; autocorrelating the data relating to each capacitor to obtain autocorrelated data; and determining, based at least on said autocorrelated data, whether moisture is present on an exterior surface of the greenhouse window. Cross-correlating data from the at least two capacitors may be performed so as to correlate data from different capacitors to obtain cross-correlated data. Then, based at least on the cross-correlated data, a type and/or amount of moisture may be determined. The cross-correlated data may also or instead be used to determine if the material detected via the autocorrelation is a material other than moisture such as dust or dirt. The cross-correlating may be performed after the autocorrelating when certain conditions are met. As an example, the cross-correlation may be performed so as to determine whether the moisture on the window is light rain, heavy rain, fog, sleet, snow, or ice (a type of moisture).

Conditions checked for in the autocorrelation function may include (i) the gradient of the normalized autocorrelation function (e.g., when there is no disturbance the absolute value of the gradient is unity and changes with disturbance), (ii) the sign of the autocorrelation function (e.g., with a CB radio turned on or with a human hand on the window the values are oscillatory with positive and negative parts), and (iii) the shape of the autocorrelation function as a function of time lag may also be used as a signature or footprint to distinguish rain from other disturbances, and this shape may also be used to distinguish between different nuances of rain or water content. Thus, cross-correlating of data from at least two capacitors is only performed when one, two or all of the following conditions are met: (a) the autocorrelated data has no negative values; (b) a gradient of an autocorrelation curve associated with said autocorrelated data is greater than one; and (c) the shape of the autocorrelation curve associated with the autocorrelated data (e.g., signal footprint) is different than a predetermined autocorrelation curve associated with normalized non-disturbed autocorrelation data (e.g., predetermined footprint). Alternatively, (c) may be replaced with (c′) the shape of the autocorrelation curve associated with the autocorrelated data (e.g., signal footprint) matches or substantially matches a predetermined autocorrelation curve (e.g., predetermined signal footprint) associated with a known moisture pattern. A symmetry level of a cross-correlation curve associated with the cross-correlated data can be determined and also used in the determination(s).

With respect to the light-sensing capabilities of certain example embodiments, as is taught by the '169 publication, for example, a printed circuit board (PCB), which may be a flexible PCB in certain example embodiments, may be supported by a glass substrate, e.g., on an interior surface thereof. The PCB may include first and second outer layers and at least one inner layer, with the first outer layer being closest to an interior of the greenhouse and the second outer layer being closest to an exterior of the greenhouse. The outer layers may each be formed from a flexible polymer, while the at least inner lay may substantially metallic. A light sensor flip-chip is mounted to an inner surface of the first outer layer of the PCB, with the light sensor flip-chip including at least two light sensor arrays, and with each said sensor array being configured to sense light of a predetermined wavelength range and/or output its intensity. The at least two light sensor arrays are arranged so as to see through a hole formed in the PCB, as the hole in the PCB acts as a lens. The wavelength ranges may correspond to visible and/or infrared ranges, and may be used to determine, for example, the distinguish between day and night conditions, the passing of a cloud during day conditions that otherwise does or does not significantly affect the spectrum of light reaching the interior of the greenhouse, etc.

Bayesian inferences may be made as to the various excitations in order to help predict the likelihood of a current or future excitations and, thus, to help improve the quality of the sensing. The source of a disturbance may be of any number of possible origins including, for example, water (e.g., as in film-wise or drop-wise condensation), human or other touch, visible and IR light, EMI, etc. These disturbances affect the capacitive sensor field (EFS) and/or light detector's incoming flux. Each of these sources of disturbances may be fingerprinted as a model “M” with their respective parameterization. Certain example embodiments that implement a Bayesian approach assume that M represents a model as well as its parameterization, I is the background information and any underlying information about data retrieval and applicability of the model, and D is data (experimental and/or numerical) that may be used to improve the knowledge of the suitability of the model M. Ultimately, a decision is made whether to admit or reject the model M based on its probability or P(M|D,I), e.g., as calculated by P(M|D,I)=P(M|I)P(D|M,I)/P(D|I).

Referring once again to FIG. 2 of the instant disclosure, temperature and/or humidity sensors 210b also may be provided. The temperature and/or humidity sensors 210b may be provided in different zones (e.g., corresponding to different areas of the greenhouse that may or may not be separated by internal walls, drop sheets, where different plants grow, and/or the like) at the same or different elevations (e.g., on the glass, suspended in air, attached to hanging plants, on the ground, and/or the like), etc. The temperature and/or humidity outside the greenhouse also may be measured in certain example embodiments.

A weather feed 210c also may be provided in certain example embodiments. In certain example embodiments, the weather feed 210c may receive packetized data or the like pushed from a central service such as, for example, the National Weather Service or the like, and may thus may be used to receive data concerning storm watches and/or warnings (including, for example, thunderstorm, hurricane, tornado, and/or other watches/warnings), flood watches and/or warnings, etc. Alternatively, or in addition, separate or integrated sensors may be configured to detect changes in barometric pressure, wind levels and/or gusts, etc.

The controller 202 receives data from these and/or other sensors in the sensor array 210 and may store a copy to a local and/or remote storage location (e.g., that possibly also backs the stored settings data store 214). The controller may consult the stored settings from the store 214 and, based on the data received from the sensor array 210, may use such data to drive one or more of the automated subsystems 212. The automated subsystems 212 may include, for example, retractable and/or repositionable window panes/panels 212a, retractable and/or repositionable shade baffles 212b, irrigation subsystems 212c, heating and/or cooling subsystems 212d, humidifier and/or dehumidifier subsystems 212e, lighting 212f, “defroster” 212g, etc.

In certain example embodiments, the defroster 212g may be an active system, e.g., that heats a thin film heatable layer or the like to remove condensation in the form of rain, ice, fog, frost, and/or the like. In certain example embodiments, pulsed heating techniques may be used in certain example embodiments, e.g., as disclosed, for example, in U.S. Pat. No. 7,518,093, the entire contents of which are hereby incorporated herein by reference. A conductive thin film layer or the like may be disposed in a pattern including lines and/or a grid. A conductive grid G formed by interspersed conductors (or electrodes) may be formed on the interior surface of the greenhouse windows. For instance, comb-shaped conductors may be provided directly on and contacting the surface of the glass substrate, and may be driven by an AC power source. In accordance with the laws of physics (e.g., Maxwell's Equations), the passing of the AC through the conductors causes electromagnetic fields to be generated, and the AC passing through the conductive structure propagate through the glass substrate and encompass and/or reach an exterior surface of the substrate and can be absorbed by ice, thereby causing the ice to melt and/or be removed from the window. Differently stated, once the de-icing circuit is driven with AC, electromagnetic energy from the circuit is coupled to ice on the exterior surface of the window. This electromagnetic energy is absorbed by the ice, thereby causing ice removal from the window via melting and/or delamination. It has been found that an AC frequency from the power source 4815 tuned to ice removal is from about 5-40 kHz, more preferably from about 10-25 kHz, and most preferably from about 10-20 kHz. It has surprisingly been found that the use of AC at this frequency causes generation of electromagnetic energy that is most efficiently absorbed by ice on the exterior surface of the door, thereby resulting in the most efficient ice removal. A sine wave and/or square wave type of AC may be used in different example embodiments. In certain example embodiments, a pulsing technique used may be the so called chirping mode whereby a sinusoidal wave is modulated by square pulses. In certain example embodiments, it has also been found that application of such AC at about 300-500 V is particularly effective at ice removal. Other frequencies may be used for fog, water droplet, and/or other moisture removal. Heating and/or cooling vents that blow forced air onto a surface of the substrate additionally or alternatively may be incorporated into the system, e.g., for defrosting and/or other related purposes.

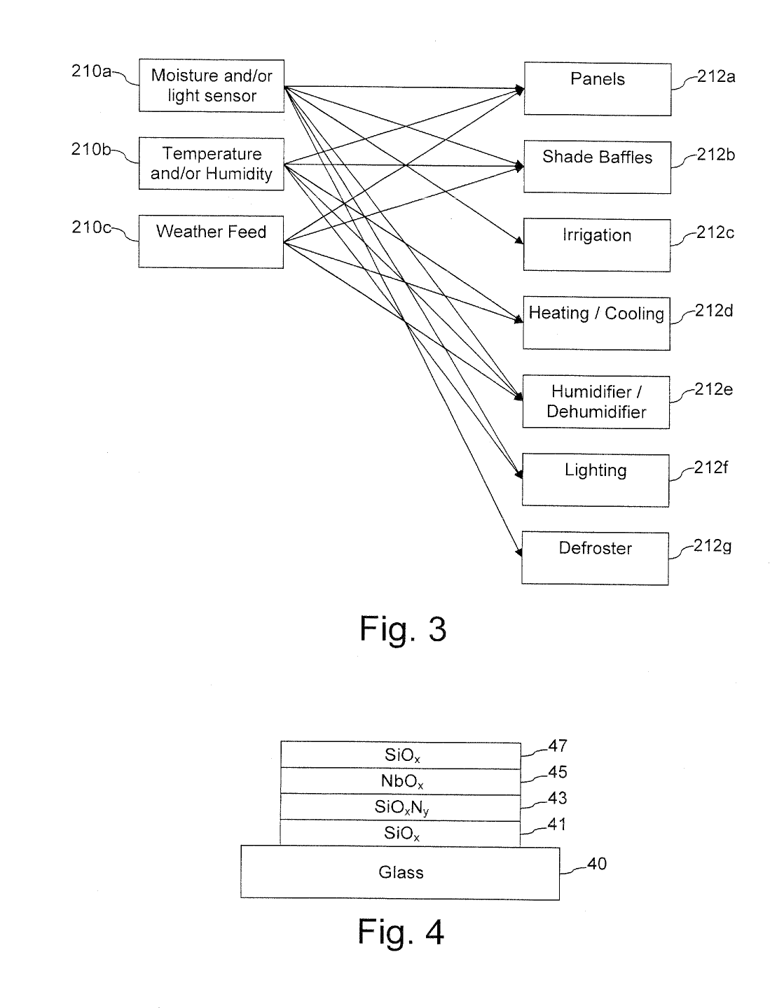

FIG. 3 is a diagram showing how output from the sensor arrays can be used to trigger different ones of the automated subsystems in accordance with certain example embodiments. As shown in FIG. 3, the moisture and/or light sensor 210a can be used to: open/close/reposition the panels 212a (e.g., to selectively prevent or allow rainfall from reaching the plants when they have been watered too much or not enough), open/close/reposition the shade baffles 212b (e.g., to selectively allow more or less direct or indirect light from reaching the plants), start/sop the irrigation system 212c (e.g., when too little or too much rainfall reaches the plants), selectively humidify or dehumidify the growing area(s) using the humidifier/dehumidifier 212e, turn on or off the lighting 212f (e.g., when the plants need more or less light), actuate the defroster 212g (e.g., to remove ice, fog, and/or other condensation built up on the substrates), etc.

The temperature and/or humidity sensors 210b may be used, for example, to: open/close/reposition the panels 212a, open/close/reposition the shade baffles 212b, activate the heating/cooling system 212d (e.g., when the temperature in the greenhouse becomes too cool or too hot), selectively humidify or dehumidify the growing area(s) using the humidifier/dehumidifier 212e, turn on or off the lighting 212f (e.g., to help build-up or reduce heat in the growing area(s)), etc.

The weather feed data 210c may be used, for example, to: open/close/reposition the panels 212a and/or the shade baffles 212b (e.g., to provide protection from a storm or the like, activate the heating/cooling system 212d, humidify or dehumidify the growing area(s) using the humidifier/dehumidifier 212e, etc.

It is noted that the mapping provided in FIG. 3 is provided by way of example. For instance, outputs from these and/or other sensors may be used to drive the automation of these and/or other systems and/or subsystems in different example embodiments.

### Example Thin Film and/or Other Coating Techniques

Certain example embodiments may involve thin film layers or layer stacks, e.g., to provide antireflective (AR), hydrophilic and/or photocatalytic, UV blocking, IR reflecting, and/or other functions. AR coatings may be provided on one or both major surfaces of the substrates in different example embodiments. Such AR coatings may be wet applied (e.g., using dip, roll, spin, slot die, meniscus, and/or other techniques), sputter deposited, and/or formed in any suitable manner. An example wet-applied coating involves blending sols with metal alkoxides and sols with silicon nanoparticles and siloxane. The formulation of a sol with silicon nanoparticles and siloxane may be as follows:

| Chem. | M.W. (g/mol) | Wt., g | Mol |
|---|---|---|---|
| NPA | 60.100 | 69.704 | 1.160 |
| Deionized water | 18.000 | 1.808 | 0.100 |
| Acetic acid (AcOH) | 60.050 | 4.889 | 0.081 |
| Tetraethyl orthosilicate (TEOS) | 208.330 | 3.636 | 0.017 |
| Nano silica particle (IPA-ST-UP) | 60.000 | 19.948 | 0.332 |

15% of elongated nano-particle in IPA-ST-UP

IPA-ST-UP: 9-15 nm of diameter and 100-140 nm of length

4 wt. % of SiO₂

A typical procedure to prepare sols with silicon nanoparticles and siloxane is as follows: 67.47 g of NPA is added to 200 ml of glass bottle with magnetic stirrer bar. To this solution, 3.636 of TEOS, 19.948 g of IPA-UP-ST and 1.808 g of Deionized water subsequently is added. Then, 4.889 g of AcOH is added to solution and the sol is stirred immediately at room temperature for 24 hours. The sol with a solid percentage of 3 wt. % is prepared by diluting with NPA.

The silica nanoparticles include about 15 wt. % amorphous silica, 85 wt. % isopropanol and less than about 1 wt. % water. If elongated silica particles are used, they can range in diameter between 9-15 nm with an average length of 40-100 nm and with the OH group present in an amount of about 5-8 OH/nm². Water-based silica nanoparticles, such as SNOWTEX from Nissan Chemical, can also be used, with the size of silica nanoparticles ranging from 10-100 nm at a weight percentage of 20-40%.

In addition to elongated silica nanoparticles, spherical silica nanoparticles, such as those produced under the trade name ORGANOSILICASO (available from Nissan Chemical), having a particle size of between 9-15/40-100 nm, a wt. % SiO₂ of 15-16%, less than 1% water, a viscosity of less than 20 mPa·s and a specific gravity of between 0.85 and 0.90, can be used. The weight percentage of spherical silica nanoparticles in solution may range from 20-40%, which corresponds to 60-80% of solvent in the silica solution. Minor amounts of water in the range from 0.3 to 3 wt. % may also be present in the final solution.

For example sols such as those in the table above, the amount of solid SiO₂ may be about 4 wt. %. But the solid percentage can be from 0.6-10 wt. %, with the amount of solvent comprising 70-97 wt. %. The amount of tetraethyl orthosilicate (TEOS) used as a binder ranges from 0.3 to 20 mol %; the amount of acetic acid (which serves as a catalyst) may range from 0.01-7 mol %; and the molar ratio of water to silica ranges from 1.1 to 50.

Although acetic acid is mentioned, other acids or bases could be used in different examples. For instance, the catalyst could be an inorganic acid, an organic acid, or an inorganic base. Inorganic acids may include, for example, hydrochloric acid, nitric acid, phosphoric acid, sulphuric acid, boric acid, hydrofluoric acid, hydrobromic acid, perchloric acid, etc. Organic acids may include, for example, lactic acid, formic acid, citric acid, oxalic acid, uric acid, etc. Inorganic bases may include, for example, ammonium carbonate, ammonium hydroxide, barium hydroxide, cesium hydroxide, magnesium hydroxide, potassium hydroxide, rubidium hydroxide, sodium hydroxide, etc.

A typical solvent used in the silica solution may include alcohol, such as isopropanol, methanol, n-propanol, and ethanol. Other solvents may include N,N-dimethyl acetamide, ethylene glycol, ethylene glycol mono-n-propyl ether, methyl ethyl ketone, ethylene oxide, formamide, dimethylformamide, acetonitrile, dioxane, tetrahydrofuran, 2-ethoxyethanol, 2,2′, 2″-nitrilotriethanol, and methyl isobutyl ketone. Isopropanol is the recommended solvent for silica nanoparticles ranging in size from 10 to 100 nm.

Other example embodiments may use blended sols that help provide both anti-corrosion and AR (ACAR) purposes. Such coatings may be used additionally or alternatively incorporate have antifog, anti-glare, anti-UV, anti-smudge, anti-static, self-cleaning, and/or other features. See, for example, U.S. application Ser. No. 13/904,421, filed on May 29, 2013, the entire contents of which are hereby incorporated herein by reference. Among other things, the '421 application discloses forming the reaction product of a hydrolysis and/or a condensation reaction of at least one hybrid alkoxide selected from the group consisting of Si(OR)₄—Al(s-OBu)₃, Si(OR)₄—B(OBu)₃ and Si(OR)₄ and Zr(OBu)₄, where R is a CH₂CH₃ group, s-OBu is sec-butoxide and OBu is n-butoxide. The solution optionally may be blended and/or mixed with silicon nanoparticles and/or siloxanes. A Tqe % gain of about 3.2% and/or refractive index of 1.5 or less is/are possible.

Sputter deposited heat treatable AR coatings are disclosed in, for example, U.S. Publication Nos. 2012/0196133, 2012/0057236, and 2011/0157703, as well as U.S. application Ser. No. 13/835,278, filed on Mar. 15, 2013. The entire contents of each of these documents are hereby incorporated by reference herein.

An AR coating with self-cleaning properties is disclosed in U.S. application Ser. No. 13/727,767 filed Dec. 27, 2012, the entire contents of which are hereby incorporated herein by reference. In certain example embodiments, an outermost layer comprising or consisting essentially of anatase TiO₂ or the like may be provided, e.g., for self-cleaning purposes.

As indicated above, sputter deposited AR coatings may be provided in certain example embodiments. See, for example, U.S. Publication Nos. 2011/0157703 and 2012/0196133, which respectively disclose heat treatable three- and four-layer sputter deposited AR coatings and are each incorporated by reference herein. Example ranges for the thicknesses of each layer of an example three-layer AR coating are as follows:

| | Range | More Preferred | Example |
|---|---|---|---|
| Layer | (nm) | (nm) | (nm) |
| SiOₓN_{y} (closest substrate) | 75-135 nm | 94-115 nm | 95 nm |
| TiOₓ (intermediate) | 10-35 nm | 12-22 nm | 21 nm |
| SiOₓ (farthest from substrate) | 70-130 nm | 89-109 nm | 105 nm |

In this example, the medium index layer comprising silicon oxynitride and may have an index of refraction of from about 1.65 to 2.0 at 380 nm, 550 nm, and 780 nm wavelengths; the high index layer may have an index of refraction of at least about 2.0 at 380 nm, 550 nm, and 780 nm wavelengths; and the low index layer may have an index of refraction of from about 1.4 to 1.6 at 380 nm, 550 nm, and 780 nm wavelengths. In certain instances, the medium index layer has compressive residual stress after heat treatment. The layer stack may be arranged in a medium/high/low index arrangement in certain example embodiments.

FIG. 4 is a cross-sectional view of a substrate supporting an optional sputter deposited four-layer heat treatable AR coating that may be used in connection with certain example embodiments. This four-layer sputtered AR coatings may include, for example, an index matching and/or stress reducing layer 41, a medium index layer 43, a high index layer 45, and a low index layer 47, in that order, moving away from the substrate 40. The index matching and/or stress reducing layer 41 may be of or include silicon oxide or silicon oxynitride, the medium index layer 43 may be of or include silicon oxynitride, the high index layer 45 may be of or include niobium oxide and/or titanium oxide, and the low index layer 47 may be of or include silicon oxide.

The index matching and/or stress reducing layer 41 may substantially match the index of refraction of the supporting glass substrate 40. By “substantially matches,” it is meant that the refractive index of the layer is within about 0.2 of the refractive index of the glass substrate, more preferably within about 0.1, and most preferably the difference is no greater than about 0.05 or 0.04. This index matching and/or stress reducing layer 41 may have a thickness of from about 50 to 300 nm, more preferably from about 60 to 120 nm, and most preferably from about 60 to 100 nm. However, a layer having any thickness sufficient to turn the net stress of the coating into compressive stress without significantly degrading the optical and/or physical characteristics of coating may be used in other example instances. The inclusion of an additional index-matching/stress-reducing layer may be advantageous because a coating including an additional layer with a higher magnitude of compressive stress has been found to have a lower overall net stress.

The medium index layer 43 may have a thickness of from about 30 to 150 nm, more preferably from about 40 to 80 nm, and most preferably from about 50 to 70 nm, with an exemplary thickness range being from about 53-65 nm. The medium index layer 43 may have a refractive index from about 1.6 to 2.0, more preferably from about 1.65 to 1.95, and most preferably from about 1.7 to 1.8 or 1.9.

The high index layer 45 may have a refractive index of from about 2.0 to 2.6, more preferably from about 2.1 to 2.5, and most preferably from about 2.2 to 2.4. The high index layer 45 may have a thickness of from about 50 to 150 nm, more preferably from about 75 to 125 nm, even more preferably from about 80 to 120 nm, and most preferably from about 85 to 105 nm. In other example instances, however, this high index layer 45 may be thinned in order to reduce the net tensile stress of the AR coating, e.g., such that it has a thickness of less than about 50 nm, or even less than about 25 nm in some instances. In further example instances, the high index layer 45 may comprise a high index material having a lesser tensile stress value, before and/or after heat treatment. In this regard, it may comprise an oxide of niobium in some instances. In other instances, it may comprise an oxide of titanium. In further example embodiments, it may comprise another suitable, high index material.

The low index layer 47 will have an index of refraction lower than that of the medium and high index layers 43 and 45, and may even have an index of refraction lower than that of the index matching and/or stress reducing layer 41. In certain examples, the refractive index of the low index layer 47 may be from about 1.3 to 1.6, more preferably from about 1.35 to 1.55, and most preferably from about 1.43 to 1.52. Its thickness may be from about 40 to 200 nm, more preferably from about 50 to 110 nm, and most preferably from about 60 to 100 nm, with an example thickness being around 80 nm.

In certain example instances, the index matching and/or stress reducing layer 41 and the low index layer 47 may have substantially the same thicknesses. For example, their thicknesses may differ by no more than about 15 nm, more preferably no more than about 10 nm, and most preferably no more than about 5 nm, according to certain example embodiments.

Plasma-enhanced chemical vapor deposition (PE-CVD) may be used to dispose durable antireflective coatings in certain example embodiments. Such PE-CVD deposited layers may include one or more silicon-inclusive index matching layers. For example, the same or similar high/medium/low index layer stack as that described above may be used in connection with certain example embodiments. Some or all of these layers may be silicon-inclusive layers (e.g., silicon oxide, silicon nitride, and/or silicon oxynitride inclusive layers) selected so as to have indexes of refraction that match or substantially match those indicated above for the like layers. In some cases, silicon carbide or silicon oxycarbide inclusive layers may be provided as protective overcoats.

Low-E coatings may for example comprise first and second dielectric layers or layer stacks sandwiching a silver-based layer. One, two, three, four, or more layers of silver may be separated by dielectric layers or layer stacks, which each dielectric layer being of or including Ti, Zn, Sn, Si, Ni, Cr, and/or combinations thereof, in metallic, oxided, nitrided, and/or oxynitrided form(s). The dielectric layers may be used to tune optical and/or other properties of the low-E coating.

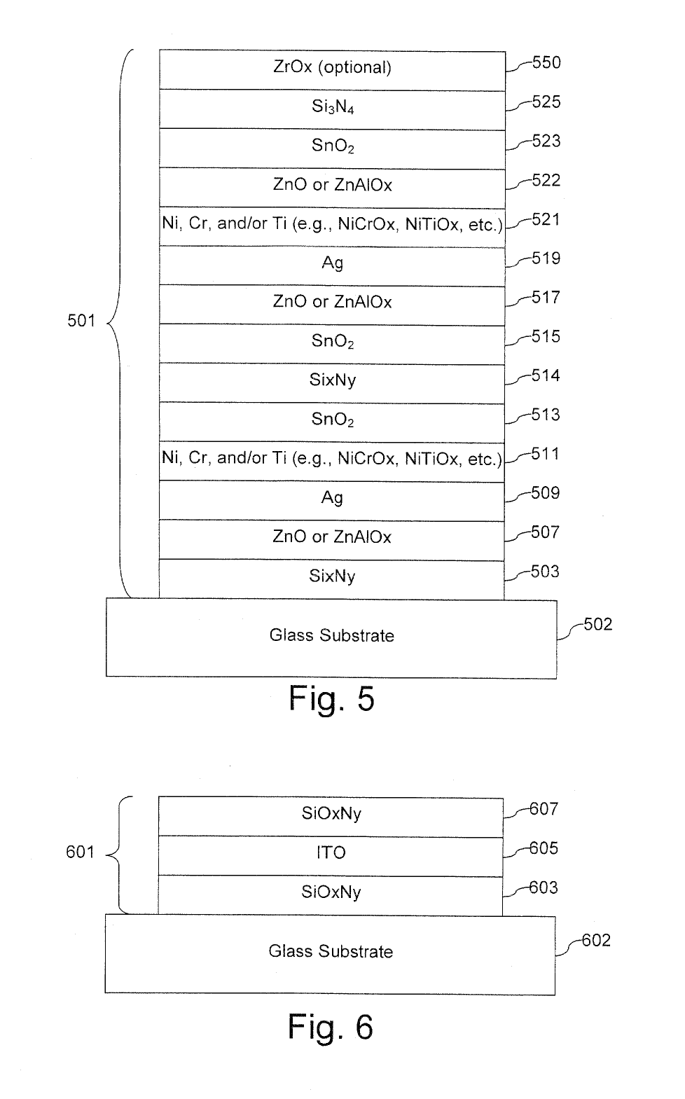

An example double silver-based low-E coating 501 that may be used in connection with certain example embodiments is shown in FIG. 5. The coating (or layer system) 501 is supported by the substrate 502 and includes: dielectric silicon nitride inclusive layer 503, which may be Si₃N₄, of the Si-rich type for haze reduction, or of any other suitable stoichiometry in different embodiments; first lower contact layer 507 (which contacts IR reflecting layer 509); first conductive and preferably metallic infrared (IR) reflecting layer 509; first upper contact layer 511 (which contacts layer 509); dielectric layer 513 (which may be deposited in one or multiple steps in different embodiments); another silicon nitride inclusive layer 514; tin oxide inclusive interlayer 515; second lower contact layer 517 (which contacts IR reflecting layer 519); second conductive and preferably metallic IR reflecting layer 519; second upper contact layer 521 (which contacts layer 519); dielectric layer 523; and protective dielectric layer 525; and optional protective durability enhancing protective layer 550, which may comprise zirconium oxide. The “contact” layers 507, 511, 517, and 521 each contact at least one IR reflecting layer (e.g., layer based on Ag). An optional dielectric layer comprising titanium oxide (e.g., TiO₂ or any other suitable stoichiometry such as, for example, substoichiometric TiOx) may be provided between the substrate and the first silver-based layer 509, e.g., for optical purposes in certain example embodiments.

The upper contact layers 511 and 521 may be of or include nickel (Ni) oxide, chromium/chrome (Cr) oxide, titanium (Ti) oxide, or a nickel alloy oxide such as nickel chrome oxide (NiCrOx), nickel titanium oxide (NiTiOx), or other suitable material(s), in certain example embodiments. The use of, for example, NiCrOx and/or NiTiOx in these layers (511 and/or 521) allows durability to be improved. The layers 511 and/or 521 may be fully oxidized in certain embodiments (i.e., fully stoichiometric), or alternatively may only be partially oxidized. In certain instances, the layers 511 and/or 521 may be at least about 50% oxidized. Contact layers 511 and/or 521 may or may not be oxidation graded in different embodiments. Oxidation grading means that the degree of oxidation in the layer changes throughout the thickness of the layer so that, for example, a contact layer may be graded so as to be less oxidized at the contact interface with the immediately adjacent IR reflecting layer than at a portion of the contact layer(s) further or more/most distant from the immediately adjacent IR reflecting layer. Contact layers 511 and/or 521 may or may not be continuous in different embodiments across the entire IR reflecting layer.

Lower contact layers 507 and/or 517 in certain embodiments are of or include zinc oxide (e.g., ZnO). The zinc oxide of layers 507 and 517 may contain other materials as well, such as, for example, Al (e.g., to form ZnAlOx). In certain example embodiments, one or more of zinc oxide layers 507 and 517 may be doped with from about 1 to 10% Al, more preferably from about 1 to 5% Al, and most preferably about 1 to 4% Al.

Alternative low-E coatings may be based on ITO or the like. For instance, an ITO-based layer may be sandwiched between first and second layers comprising silicon (e.g., layers comprising silicon oxide, silicon nitride, and/or silicon oxynitride). Such ITO-based low-E coatings may in some cases be more durable than silver-based low-E coatings, e.g., because ITO is less susceptible to corrosion than Ag and may in certain example embodiments be provided on surfaces 1 for anticondensation and/or other purposes. See, for example, U.S. Publication Nos. 2012/0164420, 2012/0048722, and 2011/0212311, the entire contents of each of which are hereby incorporated by reference.

FIG. 6 is an example ITO-based low-E coating that may be used in connection with certain example embodiments. The coating (or layer system) 601 is supported by the substrate 602 and includes: first and second silicon-inclusive dielectric layers 603 and 607 sandwiching a layer comprising ITO 605. The first and second dielectric layers 603 and 607 may be oxided and/or nitrided in certain example embodiments. For instance, the first and second dielectric layers each may be of or include SiOxNy in certain example embodiments.

Example thicknesses and indices of refraction for each of the layers is provided in the table that follows:

| | Example | First | Second | Example | Preferred | First | Second |
|---|---|---|---|---|---|---|---|
| | Thickness | Example | Example | Index of | Index of | Example | Example |
| | Range | Thickness | Thickness | Refraction | Refraction | Index of | Index of |
| | (nm) | (nm) | (nm) | Range | Range | Refraction | Refraction |
| SiOₓN_{y} | 30-100 | 60 | 70 | 1.5-2.1 | 1.7-1.8 | 1.75 | 1.7 |
| ITO | 95-160 | 105 | 105 | 1.7-2.1 | 1.8-1.93 | 1.88 | 1.9 |
| SiOₓN_{y} | 30-100 | 65 | 70 | 1.5-2.1 | 1.7-1.8 | 1.75 | 1.7 |
| Glass | N/A | N/A | N/A | N/A | N/A | N/A | N/A |

Other variants of this layer stack are possible in different embodiments of this invention. Such variants may include, for example, using partially or fully oxided and/or nitrided layers for the first and/or second silicon-inclusive layers, adding a protective overcoat comprising ZrOx, adding one or more index matching layers (e.g., comprising TiOx) between the glass substrate and the second silicon-inclusive layer, etc. For instance, certain example embodiments may involve modifying the FIG. 6 example layer stack so as to replace the top layer comprising SiOxNy with SiN, add a layer comprising ZrOx (e.g., to potentially increase durability), both replace the top layer comprising SiOxNy with SiN and add a layer comprising ZrOx, etc. Thus, it will be appreciated that the possible modifications listed herein may be used in any combination or sub-combination.

Other low-E coatings are described and/or illustrated in any of U.S. Pat. Nos. 7,998,320; 7,771,830; 7,198,851; 7,189,458; 7,056,588; and 6,887,575; and/or U.S. Publication Nos. 2012/0219821; 2012/0164420; and 2009/0115922, the entire contents of each of which are all hereby incorporated herein by reference.

The example low-E coatings discussed herein may be modified to also have UV blocking properties (e.g., blockage of light having a wavelength in the range of about 380-400 nm). Additional layers may be added to the stack for such purposes in certain example embodiments. For example, in FIG. 5, dielectric layer(s) 513, 515, and/or 523 may be “split” and an additional UV blocking layer may be added (e.g., between successive layers of the dielectric layer(s)). That is, at least some of dielectric layer(s) 513, 515, and/or 523 may be deposited, the UV blocking layer may be deposited, and then the rest of the dielectric layer(s) 513, 515, and/or 523 may be deposited. The UV blocking layer may be of or include zinc oxide doped with bismuth (e.g., ZnBiO or other suitable stoichiometry) or simply bismuth oxide (BiO) in certain example embodiments. In certain other example embodiments, the UV blocking layer may include silver oxide (e.g., AgOₓ or other suitable stoichiometry), as described, for example, in U.S. Pat. No. 6,596,399, the entire contents of which is hereby incorporated herein by reference. In still other example embodiments, a UV blocking layer surrounded by dielectric layers (e.g., of tin oxide) may be located anywhere in the low-E stack. Preferably, no more than about 20% of light having a wavelength of from 380-400 passes through the low-E coating. In certain example embodiments, the UV blocking layer is positioned so as to not directly contact the first and second IR reflecting layers.

“Bird friendly” coatings may be provided in certain example embodiments in place of or in addition to low-E coatings in certain example embodiments. See, for example, U.S. patent application Ser. No. 13/716,320 filed Dec. 17, 2012, as well as U.S. Pat. No. 8,114,488, both of which are hereby incorporated herein in their entireties.

### Example Patterning Techniques for Haze and/or Diffusion

As noted above, glass can be etched (e.g., using acid-based etchants such as HE-inclusive acid-based etchants and/or mechanical means such as sand blasting) to provide a textured morphology suitable for the scattering of unwanted infrared (IR) wavelengths to shallow angles for their dissipation, and/or the scattering of the visible light components to steeper angles to provide their effective absorption by the plants. Conventional chemical and mechanical treatments sometimes result in individual features of the textured surface having sizes on the order of tens or hundreds of microns. By contrast, the most useful wavelengths of sunlight in greenhouse applications tend to be those between about 300-800 nm, which are responsible for morphogenesis. This includes those wavelengths between about 400-700 nm that are responsible for photosynthesis of the plants. Wavelengths that are greater than about 800 nm generally are considered parasitic by those skilled in the art because they are responsible for the generally unwanted increase in the greenhouse temperature. Certain example embodiments thus may incorporate chemical and/or mechanical treatments that create features sizes appropriate for these lower wavelength ranges. In some example instances, one or more abrasive mechanical treatments may be used prior to one or more chemical treatments with the same or different etchants, or vice versa. In other example instances, mechanical and chemical treatments may alternate in any appropriate order. Embossed and/or shaped rollers may be used on one or both sides of the glass, e.g., before and/or after annealing, in order to transfer a desired pattern onto the glass.

In these and/or other example embodiments, preferential scattering of the IR components to shallow angles and visible light components to steeper angles relative to the glass substrate may be made possible using a coating. See, for example, U.S. Publication No. 2012/0251773, the entire contents of which are hereby incorporated herein by reference. The coating may include at least one thin-film layer that is textured so as to have surface features on the order of 0.1-5 microns, more preferably on the order of 0.3-3 microns that cause (a) light having a wavelength of greater than or equal to about 800 nm incident thereon to primarily scatter to angles less than 30 degrees relative to a major surface of the substrate and (b) light having a wavelength of less than or equal to about 700 nm incident thereon to primarily scatter to angles greater than 20 degrees relative to the major surface of the substrate. The thin-film coating may have a high refractive index (n), e.g., of about 1.8-2.2 (at 550 nm), more preferably about 1.9-2.1 (at 550 nm). The thickness of the coating may be about 100-10,000 nm, more preferably 200-1,000 nm.

The light scattering coating may be a single layer or a multi-layer coating in different instances. In the case of single layer coatings, for example, crystalline or polycrystalline thin-films may be used in certain example embodiments. Of course, other single layer coatings may include thin films with other crystallinities. In addition, multiple layer thin film coatings may include one or more crystalline or polycrystalline thin-films of the same or different materials.

A crystalline thin-film coating may include one or more layers of or including tin oxide, zinc oxide, combinations of zinc oxide and tin oxide, and/or any other suitable texturable crystalline or polycrystalline material. Protective overcoats of or including zirconium (e.g., zirconium oxide), silicon (e.g., silicon oxide, silicon nitride, silicon oxinitride, etc.), DLC, and/or the like may be used. In certain example embodiments, a photocatalytic material (such as anatase TiO₂ or the like) may be disposed over the textured material to provide for self-cleaning and/or other features.

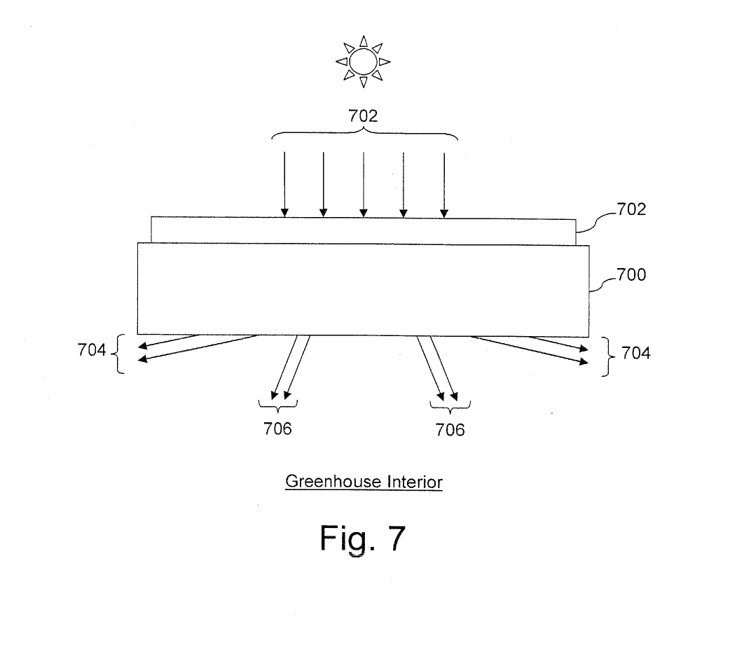

FIG. 7 is a schematic view illustrating operational principles of a light scattering coating that may be used in connection with certain example embodiments. In the FIG. 7 example, the coating 702 is disposed on an outer major surface of the substrate 700. Light 702 incident on the coating is influenced by the features of the coating 702. More particularly, long wavelength light preferably is scattered along first, low angles relative to the inner major surface of the substrate 700, whereas shorter wavelength light (e.g., in the visible range) is preferably scattered along second angles that are greater than the first, low angles, or not scattered very much at all. In some cases, transmitted near-infrared and infrared light 704 (e.g., light having a wavelength greater than or equal to about 700 nm) preferably is primarily scattered to angles less than about 30 degrees relative to the plane of the glass. In certain example embodiments, transmitted near-infrared and infrared light 704 having a wavelength greater than or equal to about 800 nm is primarily scattered to angles less than 20 degrees relative to the plane of the glass. By contrast, light 706 having a wavelength less than or equal to about 800 nm is primarily scattered to angles greater than about 20 degrees relative to the plane of the glass.

In certain example instances, light at a particular wavelength or in a particular wavelength range is “primarily scattered” to a particular range of angles if at least a majority of light at that wavelength or wavelength range is scattered within that particularly described range of angles. Of course, higher percentages of scattering beyond a simple majority may be desirable in certain example embodiments. For instance, in certain example embodiments, it may be desirable to scatter 60%, 75%, 80%, or more light at a particular wavelength or wavelength range.

In certain example instances, solar light transmission preferably exceeds 85%, more preferably 90%. Despite the high total solar light transmission, example embodiments are still advantageous, for example, because of the patterns of light, e.g., in which long wavelength light that is generally viewed as detrimental to plant growth is primarily scattered along low angles close to an inner surface of the substrate whereas shorter wavelength light that is generally viewed as beneficial to plant growth is primarily scattered along greater angles.

In order to create the desired features, wet etchants may be used. Such wet etchants may include weak acids including, for example, acetic acid, diluted acetic acid, various concentrations of hydrochloric acid (HCl), and the like. Of course, other acid etchants may be used in different example implementations. In certain instances, the weak acid may be any acid having a pH of from about 1 to 6, more preferably from about 2 to 5, and most preferably from about 2.5 to 4.5.

In some cases, double-agent etchants may be used, advantageously resulting in a texturing of the coating that has different types of feature sizes. This may be advantageous to scatter harmful wavelengths of light away from plant life while also specifically focusing beneficial wavelengths of light at the plant life. Thus, using double-agent etchants and/or more than one type of etchant may advantageously produce a layer with more than one type of feature size in some cases. The double-agent etchant may comprise dilute acetic acid (e.g., CH₃COOH) and ammonium chloride (e.g., NH₄Cl). In certain example instances, the dilute acetic acid and ammonium chloride may be in an aqueous solution. A double-agent etchant comprising dilute acetic acid and ammonium chloride may be used for etching the layer. The addition of the ammonium chloride may improve the size and smoothness of the features on the textured surface and may also result in the formation of a wider distribution of feature sizes. The ratio of ammonium chloride to acetic acid in an aqueous solution ranges from (0.1-5%) NH4Cl to (0.5-10%) CH₃COOH.

In some cases, the surface of the coating may be textured using a mixture of dilute acetic acid and phosphoric acid. The phosphoric acid may be dilute, as well, in certain instances. The ratio of phosphoric acid to acetic acid in an aqueous solution ranges from (0.1-5%) H₃PO₄ to (0.5-10%) CH₃COOH.

It will be appreciated that the feature size as discussed herein relates to a diameter or distance across a roughened region of the coating. It is noted that in addition to providing for desirable selective light diffusion, such techniques may also provide for good haze values for the greenhouse.

### Example Glass Compositions

Certain example embodiments may be used in connection with soda lime silicate glass, and/or so-called low-iron glass. For instance, the substrates may be low-iron glass substrate. Low-iron glass is described in, for example, U.S. Pat. Nos. 7,893,350; 7,700,870; 7,557,053; 6,299,703; and 5,030,594, and U.S. Publication Nos. 2006/0169316; 2006/0249199; 2007/0215205; 2009/0223252; 2010/0122728; 2010/0255980; and 2011/0275506. The entire contents of each of these documents are hereby incorporated herein by reference. The thicknesses may be, for example, 1.0-10.0 mm, more preferably 3.0-6.0 mm. The glass composition may be selected so that the substrate and/or the substrate with coatings thereon has a desired visible transmission, e.g., LT89%, LT90%, LT91%, and/or the like.

An exemplary soda-lime-silica base glass according to certain embodiments of this invention, on a weight percentage basis, includes the following basic ingredients:

| Ingredient | Wt. % |
|---|---|
| SiO₂ | 67-75% |
| Na₂O | 10-20% |
| CaO | 5-15% |
| MgO | 0-7% |
| Al₂O₃ | 0-5% |
| K₂O | 0-5% |

Other minor ingredients, including various conventional refining aids, such as SO₃, carbon, and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO. In addition to the base glass (e.g., see the table above), in making glass according to certain embodiments, the glass batch includes materials (including colorants and/or oxidizers) that cause the resulting glass to be fairly neutral in color (slightly yellow in certain example embodiments, indicated by a positive b* value) and/or have a high visible light transmission. These materials may either be present in the raw materials (e.g., small amounts of iron), or may be added to the base glass materials in the batch (e.g., antimony and/or the like). The resulting glass has visible transmission of at least 75%, more preferably at least 80%, even more preferably of at least 85%, and most preferably of at least about 90% (sometimes at least 91%) (Lt D65). Tuning within these ranges may be desirable, e.g., as noted above.

In addition to the base glass, the glass and/or glass batch comprises or consists essentially of materials as set forth in the following table (in terms of weight percentage of the total glass composition):

| | General | More Preferred | Most Preferred |
|---|---|---|---|
| Ingredient | (Wt. %) | (Wt. %) | (Wt. %) |
| total iron (ex- | 0.001-0.06% | 0.005-0.045% | 0.01-0.03% |
| pressed as Fe₂O₃) | | | |
| % FeO | 0-0.0040% | 0-0.0030% | 0.001-0.0025% |
| glass redox (FeO/ | <=0.10 | <=0.06 | <=0.04 |
| total iron) | | | |
| cerium oxide | 0-0.07% | 0-0.04% | 0-0.02% |
| antimony oxide | 0.01-1.0% | 0.01-0.5% | 0.1-0.3% |
| SO₃ | 0.1-1.0% | 0.2-0.6% | 0.25-0.5% |
| TiO₂ | 0-1.0% | 0.005-0.4% | 0.01-0.04% |

The antimony may be added to the glass batch in the form of one or more of Sb₂O₃ and/or NaSbO₃. Note also Sb(Sb₂O₅). The use of the term antimony oxide herein means antimony in any possible oxidation state, and is not intended to be limiting to any particular stoichiometry.

The low glass redox evidences the highly oxidized nature of the glass. Due to the antimony (Sb), the glass is oxidized to a very low ferrous content (% FeO) by combinational oxidation with antimony in the form of antimony trioxide (Sb₂O₃), sodium antimonite (NaSbO₃), sodium pyroantimonate (Sb(Sb₂O₅)), sodium or potassium nitrate and/or sodium sulfate. In certain example embodiments, the composition of the glass substrate includes at least twice as much antimony oxide as total iron oxide, by weight, more preferably at least about three times as much, and most preferably at least about four times as much antimony oxide as total iron oxide.

The colorant portion may be substantially free of other colorants (other than potentially trace amounts) in certain example instance. However, it will be appreciated that amounts of other materials (e.g., refining aids, melting aids, colorants and/or impurities) may be present in the glass in certain other embodiments. For instance, the glass composition may be substantially free of, or free of, one, two, three, four or all of: erbium oxide, nickel oxide, cobalt oxide, neodymium oxide, chromium oxide, and selenium. The phrase “substantially free” means no more than 2 ppm and possibly as low as 0 ppm of the element or material.

The total amount of iron present in the glass batch and in the resulting glass, i.e., in the colorant portion thereof, is expressed herein in terms of Fe₂O₃ in accordance with standard practice. This, however, does not imply that all iron is actually in the form of Fe₂O₃ (see discussion above in this regard). Likewise, the amount of iron in the ferrous state (Fe²⁺) is reported herein as FeO, even though all ferrous state iron in the glass batch or glass may not be in the form of FeO. Iron in the ferrous state (Fe²⁺; FeO) is a blue-green colorant, while iron in the ferric state (Fe³⁺) is a yellow-green colorant; and the blue-green colorant of ferrous iron is of particular concern, since as a strong colorant it introduces significant color into the glass which can sometimes be undesirable when seeking to achieve a neutral or clear color.

In view of the above, glasses according to certain example embodiments of this invention achieve a neutral or substantially clear color and/or high visible transmission. In certain embodiments, resulting glasses according to certain example embodiments of this invention may be characterized by one or more of the following transmissive optical or color characteristics when measured at a thickness of from about 1 mm-6 mm (most preferably a thickness of about 3-4 mm; this is a non-limiting thickness used for purposes of reference only) (Lta is visible transmission %). It is noted that in the table below the a* and b* color values are determined per Ill. D65, 10 degree Obs.

| | | More | Most |
|---|---|---|---|
| Characteristic | General | Preferred | Preferred |
| Lta (Lt D65): | >=85% | >=90% | >=91% |
| % τe (ISO 9050): | >=85% | >=90% | >=91% |
| % FeO (wt. %): | <=0.004% | =0.003% | <=0.0020% |
| L* (Ill. D65, 10 deg.): | 90-99 | n/a | n/a |
| a* (Ill. D65, 10 deg.): | −1.0 to +1.0 | −0.5 to +0.5 | −0.2 to 0.0 |
| b* (Ill. D65, 10 deg.): | 0 to +1.5 | +0.1 to +1.0 | +0.2 to +0.7 |

It is noted that although certain glasses are described as having a neutral color, it may in some instances be desirable to provide greenhouse glass with a green or at least greenish color, e.g., for sometimes desired aesthetic purposes.

### Example Bending Techniques

U.S. Pat. Nos. 8,303,124; 7,150,916; 7,140,204; 7,082,260; 6,602,371, as well as U.S. Publication Nos. 2011/0176236 and 2007/0291384, for example, disclose techniques for hot and/or cold bending glass, e.g., in connection with solar and/or automotive applications. These and/or other techniques may be used to bend the substrates described herein, and the entire contents of each of these documents are hereby incorporated herein by reference. In certain example embodiments, the substrates may be coated, optionally sized (e.g., by cutting), and then bent (together with or separate from an optional heat treatment operation).

In certain example embodiments, glass substrates may be laminated to other substrates, e.g., via a polymer inclusive interlayer or the like. Example laminating materials include, for instance, PVB, EVA, PET, PMMA, PU, etc. Sensors may be provided on any appropriate surface (e.g., surface 4), and/or embedded in the laminating material, in different example embodiments. Similarly, coatings may be applied to any one or more surfaces. For example, an ITO low-E coating may be applied to surface(s) 1 and/or 4, an AR coating may be provided to each surface a low-E coating is not provided on, a silver-based low-E coating may be applied to surface(s) 2 and/or 3, self-cleaning coatings may be provided on one or both exterior major surfaces, etc. The substrates used in laminated products may be of the same, similar, or different compositions, in different embodiments.

In a similar fashion, certain example embodiments may involve insulating glass (IG) units, with the sensors and/or coatings provided in corresponding locations. IG units may comprise first and second substantially parallel spaced apart glass substrates. A spacer system provided around the periphery of the unit may help define a gap between the substrates and at least partially define a cavity. The cavity may be backfilled with a Nobel gas (e.g., Ar, Kr, Xe, and/or the like), alone and/or in combination with air. The substrates used in such IG units products may be of the same, similar, or different compositions, in different embodiments. So-called triple glaze IG units also may be provided in different example embodiments, the difference relating to the presence of a third substrate and a second cavity. It is noted that a laminated product may be used in place of one or more of the substrates in an IG unit.

Vacuum insulated glass (VIG) units also may be provided. VIG units may include first and second substantially parallel spaced apart glass substrates. An edge seal may be provided around a periphery of the unit, and a plurality of pillars located in the gap or cavity that is evacuated to a pressure less than atmospheric may help support the substrates in this relation. The sensors and/or coatings provided in locations corresponding to those identified above in certain example embodiments.

The terms “heat treatment” and “heat treating” as used herein mean heating the article to a temperature sufficient to achieve thermal tempering and/or heat strengthening of the glass inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, or up to about 10 minutes, in certain example embodiments.

“Peripheral” and “edge” seals herein do not mean that the seals are located at the absolute periphery or edge of the unit, but instead mean that the seal is at least partially located at or near (e.g., within about two inches) an edge of at least one substrate of the unit. Likewise, “edge” as used herein is not limited to the absolute edge of a glass substrate but also may include an area at or near (e.g., within about two inches) of an absolute edge of the substrate(s).

Although a layer, layer system, coating, or the like, may be said to be “on” or “supported by” a substrate, layer, layer system, coating, or the like, other layer(s) may be provided therebetween. Thus, for example, the paints, coatings, and/or layers described above may be considered “on” and “supported by” the substrate and/or other paints, coatings, and/or layers even if other layer(s) are provided therebetween.

In certain example embodiments, a greenhouse is provided. A plurality of glass windows at least partially defines a roof and a sidewall of the greenhouse. At least some of the glass windows comprise a substantially planar glass substrate that supports an antireflective coating on at least one major surface thereof and also has features formed thereon, with the features being sized, shaped, and arranged to scatter light in a first wavelength range in a first direction and to scatter light in a second wavelength range in a second direction. The first and second wavelength ranges and the first and second directions respectively are different from one another. At least one sensor is mounted to at least one of the glass windows. At least one automated subsystem is provided for the greenhouse. A controller, including at least one processor and a memory, is configured to send control signals to the at least one automated subsystem based on data received from the at least one sensor (e.g., to open/close/vent/reposition panels and/or shade baffles, start/stop irrigation, adjust heating/cooling, humidify/dehumidify the chamber, turn on/off lighting, actuate/deactivate a defroster, etc.).

In addition to the features of the previous paragraph, in certain example embodiments, the controller may be operably connected to a data store that stores user-customizable settings defining how the controller is to use data received from the at least one sensor to drive the at least one automated subsystem.

In addition to the features of either of the two previous paragraphs, in certain example embodiments, the at least one automated subsystem may comprise a window opening/closing system; and/or the at least one sensor may include moisture and/or humidity sensors.

In addition to the features of the previous paragraph, in certain example embodiments, the controller may be programmable to actuate the window opening/closing system in dependence on data received from the moisture and humidity sensors such that: at least one window of the greenhouse is to be closed when a threshold level of moisture is detected by the moisture sensor, and/or at least one window of the greenhouse is to be opened to promote venting of the greenhouse when a threshold level of humidity is detected in the greenhouse by the humidity sensor.

In addition to the features of any of the four previous paragraphs, in certain example embodiments, the at least one automated subsystem may comprise a shade baffle opening/closing system; and/or the at least one sensor may include a light sensor.

In addition to the features of the previous paragraph, in certain example embodiments, the controller may be programmable to actuate the shade baffle opening/closing system in dependence on data received from the light sensor such that at least one shade baffle of the greenhouse is to be closed when a threshold amount of sunlight in a predetermined wavelength range has impinged upon the light sensor.

In addition to the features of any of the six previous paragraphs, in certain example embodiments, a low-emissivity coating may be supported by a major surface of at least one of the glass windows.

In addition to the features of the previous paragraph, in certain example embodiments, the low-emissivity coating may be provided on an outermost surface of its supporting window and/or may comprise a layer comprising ITO sandwiched between first and second silicon-inclusive layers.

In addition to the features of the previous paragraph, in certain example embodiments, the at least one sensor may include a moisture sensor and/or the controller may be configured to send AC to the ITO in the low-emissivity coating via the at least one automated subsystem when the moisture sensor detects moisture of one of a plurality of predefined types on the window.

In addition to the features of the previous paragraph, in certain example embodiments, the predefined types may include fog, frost, and/or ice.

In addition to the features of any of the ten previous paragraphs, in certain example embodiments, the features may scatter light having a wavelength range less than 700 nm in the first direction and having a wavelength range greater than 800 nm in the second direction.

In addition to the features of any of the 11 previous paragraphs, in certain example embodiments, the features may be formed via mechanical means performed on, and/or acid etching of, the window(s) on which they are formed.

In addition to the features of any of the 12 previous paragraphs, in certain example embodiments, the features may be formed in a thin film coating disposed on the substrate.

In certain example embodiments, a method of making a window for a greenhouse comprises: providing a substantially planar glass substrate; disposing an antireflective coating on one or both major surfaces of the substrate; forming light scattering features on one of the major surfaces of the substrate, with the features being sized, shaped, and arranged to scatter light in a first wavelength range in a first direction and to scatter light in a second wavelength range in a second direction, and with the first and second wavelength ranges and the first and second directions respectively being different from one another; and mounting at least one sensor to the substrate, with the at least one sensor being configured to gather information relevant to operation of a greenhouse in which the window is installed and having a data output lead connectable to a controller.

In addition to the features of the previous paragraph, in certain example embodiments, the substrate may be laminated to another substrate via a polymer-based interlayer.

In addition to the features of either of the two previous paragraphs, in certain example embodiments, the features may scatter light having a wavelength range less than 700 nm in the first direction and having a wavelength range greater than 800 nm in the second direction.

In addition to the features of any of the three previous paragraphs, in certain example embodiments, the features may be formed via mechanical means performed on, and/or acid etching of, the window(s) on which they are formed.

In addition to the features of any of the four previous paragraphs, in certain example embodiments, the features may be formed in a thin film coating disposed on the substrate.

In addition to the features of any of the five previous paragraphs, in certain example embodiments, the substrate may be bent after the antireflective coating is disposed thereon and/or prior said mounting of the at least one sensor.

In addition to the features of any of the six previous paragraphs, in certain example embodiments, a multi-layer low-emissivity coating may be sputter deposited on the substrate, with the multi-layer low-emissivity coating optionally comprising first and second silicon-inclusive layers sandwiching a layer comprising ITO.

In addition to the features of any of the seven previous paragraphs, in certain example embodiments, a multi-layer low-emissivity coating may be sputter deposited on the substrate, with the multi-layer low-emissivity coating optionally comprising at least one infrared reflecting layer comprising silver sandwiched between at least first and second dielectric layer stacks.

In addition to the features of either of the two previous paragraphs, in certain example embodiments, the substrate may be bent after the antireflective coating and/or the multi-layer low-emissivity coating is/are disposed thereon.

In addition to the features of any of the nine previous paragraphs, in certain example embodiments, the antireflective coating may be wet applied in connection with a sol.

In certain example embodiments, a method of assembling a greenhouse is provided. A greenhouse window or the like made according to the example techniques disclosed herein (e.g., possibly in connection with the techniques set forth in any of the previous 23 paragraphs) is provided. A plurality of substrates also is provided. The window and the substrates are built into the greenhouse as parts of the roof and/or sidewalks), with the at least one sensor being on the greenhouse's interior. The data output lead from the at least one sensor of the window is connected to a programmable controller. Automated subsystems of the greenhouse are connected to the programmable controller. The automated subsystems comprise one or more of openable/closable windows and/or shade baffles, irrigation, a heating and/or cooling unit, and/or lighting.

In addition to the features of the previous paragraph, in certain example embodiments, the window and/or at least some of the substrates may be curved.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A greenhouse, comprising:
a plurality of glass windows at least partially defining a roof and a sidewall of the greenhouse, at least some of the glass windows comprising a substantially planar glass substrate that supports an antireflective coating on at least one major surface thereof and also having features formed thereon, the features being sized, shaped, and arranged to scatter light in a first wavelength range in a first direction and to scatter light in a second wavelength range in a second direction, the first and second wavelength ranges and the first and second directions respectively being different from one another;
at least one sensor mounted to at least one of the glass windows;
at least one automated subsystem; and
a controller, including at least one processor and a memory, configured to send control signals to the at least one automated subsystem based on data received from the at least one sensor.

2. The greenhouse of claim 1, wherein the controller is operably connected to a data store that stores user-customizable settings defining how the controller is to use data received from the at least one sensor to drive the at least one automated subsystem.

3. The greenhouse of claim 1, wherein:
the at least one automated subsystem comprises a window opening/closing system; and
the at least one sensor includes moisture and humidity sensors.

4. The greenhouse of claim 3, wherein the controller is programmable to actuate the window opening/closing system in dependence on data received from the moisture and humidity sensors such that:
at least one window of the greenhouse is to be closed when a threshold level of moisture is detected by the moisture sensor, and
at least one window of the greenhouse is to be opened to promote venting of the greenhouse when a threshold level of humidity is detected in the greenhouse by the humidity sensor.

5. The greenhouse of claim 1, wherein:
the at least one automated subsystem comprises a shade baffle opening/closing system; and
the at least one sensor includes a light sensor.

6. The greenhouse of claim 5, wherein the controller is programmable to actuate the shade baffle opening/closing system in dependence on data received from the light sensor such that at least one shade baffle of the greenhouse is to be closed when a threshold amount of sunlight in a predetermined wavelength range has impinged upon the light sensor.

7. The greenhouse of claim 1, wherein a low-emissivity coating is supported by a major surface of at least one of the glass windows.

8. The greenhouse of claim 7, wherein the low-emissivity coating is provided on an outermost surface of its supporting window and comprises a layer comprising ITO sandwiched between first and second silicon-inclusive layers.

9. The greenhouse of claim 8, wherein the at least one sensor includes a moisture sensor and the controller is configured to send AC to the ITO in the low-emissivity coating via the at least one automated subsystem when the moisture sensor detects moisture of one of a plurality of predefined types on the window.

10. The greenhouse of claim 9, wherein the predefined types include fog, frost, and ice.

11. The greenhouse of claim 1, wherein the features scatter light having a wavelength range less than 700 nm in the first direction and having a wavelength range greater than 800 nm in the second direction.

12. The greenhouse of claim 1, wherein the features are formed via mechanical means performed on, and/or acid etching of, the window(s) on which they are formed.

13. The greenhouse of claim 1, wherein the features are formed in a thin film coating disposed on the substrate.

14. A method of making a window for a greenhouse, the method comprising:
providing a substantially planar glass substrate;
disposing an antireflective coating on one or both major surfaces of the substrate;
forming light scattering features on one of the major surfaces of the substrate, the features being sized, shaped, and arranged to scatter light in a first wavelength range in a first direction and to scatter light in a second wavelength range in a second direction, the first and second wavelength ranges and the first and second directions respectively being different from one another; and
mounting at least one sensor to the substrate, the at least one sensor being configured to gather information relevant to operation of a greenhouse in which the window is installed and having a data output lead connectable to a controller.

15. The method of claim 14, further comprising laminating the substrate to another substrate via a polymer-based interlayer.

16. The method of claim 14, wherein the features scatter light having a wavelength range less than 700 nm in the first direction and having a wavelength range greater than 800 nm in the second direction.

17. The method of claim 14, wherein the features are formed via mechanical means performed on, and/or acid etching of, the window(s) on which they are formed.

18. The method of claim 14, wherein the features are formed in a thin film coating disposed on the substrate.

19. The method of claim 14, further comprising bending the substrate after the antireflective coating is disposed thereon and prior said mounting of the at least one sensor.

20. The method of claim 14, further comprising sputter depositing a multi-layer low-emissivity coating on the substrate, the multi-layer low-emissivity coating comprising first and second silicon-inclusive layers sandwiching a layer comprising ITO.

21. The method of claim 14, further comprising sputter depositing a multi-layer low-emissivity coating on the substrate, the multi-layer low-emissivity coating comprising at least one infrared reflecting layer comprising silver sandwiched between at least first and second dielectric layer stacks.

22. The method of claim 21, further comprising bending the substrate after the antireflective coating and the multi-layer low-emissivity coating are disposed thereon.

23. The method of claim 14, wherein the antireflective coating is wet applied in connection with a sol.

24. A method of assembling a greenhouse, the method comprising:
providing a window made according to the method of claim 14;
providing a plurality of substrates;
building the window and the substrates into the greenhouse as parts of the roof and/or sidewall(s), the at least one sensor being on the greenhouse's interior;
connecting the data output lead from the at least one sensor of the window to a programmable controller; and
connecting automated subsystems of the greenhouse to the programmable controller,
wherein the automated subsystems comprise one or more of openable/closable windows and/or shade baffles, irrigation, a heating and/or cooling unit, and/or lighting.

25. The method of claim 24, wherein the window and/or at least some of the substrates are curved.
